(19) United States
(12) Patent Application Publication
(10) Pub. No.: US 2009/0289344 A1
(43) Pub. Date: Nov. 26, 2009

(54) Semiconductor device

(75) Inventor: Akira Morozumi, Okaya-shi (JP)

Correspondence Address: KANESAKA BERNER AND PARTNERS LLP, 1700 DIAGONAL RD, SUITE 310, ALEXANDRIA, VA, 22314-2848, US

(73) Assignee: FUJI ELECTRIC DEVICE TECHNOLOGY CO., LTD., Tokyo (JP)

(21) Appl. No.: 12/453,453

(22) Filed: May 12, 2009

(30) Foreign Application Priority Data
May 23, 2008 (JP) 2008-135086

(51) Int. Cl. H01L 23/48; H01L 23/498; H01L 23/467

(52) U.S. Cl. 257/690; 257/703; 257/722; 257/E23.06; 257/E23.01; 257/E23.099

(57) ABSTRACT

A semiconductor device includes an insulating substrate; at least one semiconductor element mounted on a first principal surface of the insulating substrate; and a heat radiator joined through a solder member to a second principal surface of the insulating substrate opposite to the first principal surface on which the semiconductor element is mounted. The solder member contains at least tin and antimony, and the antimony content of the solder member is in a range of from 7% by weight to 15% by weight, both inclusively. Thus, reliability of the semiconductor device is improved.

### BACKGROUND OF THE INVENTION AND RELATED ART STATEMENT

The present invention relates to a semiconductor device. Particularly, it relates to a semiconductor device configured so that an insulating substrate having a semiconductor element mounted thereon is joined onto a heat radiator.

Power semiconductor modules operable under a large-current high-voltage environment have been used in various fields, for example, for general industrial purposes and in-vehicle purposes in recent years. The power semiconductor modules employ semiconductor devices such as IGBTs (Insulated Gate Bipolar Transistors), power MOSs (Metal Oxide Semiconductors) and FWDs (Free Wheel Diodes).

For example, a semiconductor device has a semiconductor element mounted on an insulating substrate of ceramics. When the semiconductor device is operated, the semiconductor element generates heat. The insulating substrate of the semiconductor device is joined to a metal heat radiator such as a heat radiating fin by a solder member. The heat generated by the semiconductor element is radiated to the outside through the heat radiator to thereby cool the semiconductor device (e.g. see Patent Document 1).

Because the semiconductor device in which the insulating substrate and the heat radiator having a large difference in heat expansion coefficient from the insulating substrate are joined by a solder member is used in various environments, for example, for general industrial purposes and in-vehicle purposes as described above, high reliability is required in the semiconductor device. Therefore, a member, such as an aluminum-silicon carbide (Al—SiC) composite material or a copper-molybdenum (Cu—Mo) composite material, having a heat expansion coefficient close to that of the insulating substrate is used as the heat radiator. A new structure for joining the insulating substrate and the heat radiator to each other without use of any solder member has been further proposed.

The semiconductor device improved in reliability by the aforementioned method, however, has the following problem. First, the Al—SiC composite material or the Cu—Mo composite material used as the heat radiator is expensive and low in recycling efficiency. In the structure for joining the insulating substrate and the heat radiator to each other without use of any solder member, the cost for reducing contact thermal resistance increases and the work for attaching the structure to a power semiconductor module is complicated.

Therefore, to obtain a low-cost semiconductor device with high reliability, a solder member containing tin (Sn) as a main component and about 5% by weight of antimony (Sb) has been used for joining the insulating substrate and the heat radiator to each other. Such a solder member can be used according to a conventional assembling method and a manufacturing apparatus. A solder member that is obtained as described above can have a lifetime of 3000 cooling-and-heating cycles. Both high reliability and low cost can be satisfied by the solder member. At present, use of the solder member, an aluminum oxide (Al₂O₃) type insulating substrate and a metal type heat radiator is chiefly the most suitable combination.

Higher reliability will be required as the power semiconductor module will be used for various purposes in the future. With respect to the aforementioned structure of the most suitable combination, it is necessary to attain higher reliability while the cost is kept low. It is therefore necessary to provide an insulating substrate using high heat-conductive ceramics such as aluminum nitride (AlN) and silicon nitride (Si₃N₄), which is high in heat conductivity, because of increase of heating density caused by size reduction and power increase.

[Patent Document 1] JP-A-2006-202884

The insulating substrate using high heat-conductive ceramics such as AlN and Si₃N₄ is higher in heat conductivity but lower in heat expansion coefficient than an Al₂O₃ type insulating substrate. For this reason, if the ceramic type insulating substrate is used in combination with a heat radiator of Cu, the heat expansion coefficient difference between the insulating substrate and the heat radiator becomes larger than that in the case where the Al₂O₃ type insulating substrate is used.

For this reason, if the insulating substrate of AlN or Si₃N₄ is used in combination with the heat radiator of Cu, stress imposed on the solder member becomes larger than that in the case where the Al₂O₃ type insulating substrate is used in combination with the heat radiator of Cu. Accordingly, there is a problem that the lifetime indicated by the number of cooling-and-heating cycles decreases and reliability decreases even when the solder member contains about 5% by weight of Sb which is relatively resistant to thermal deterioration.

The invention has been developed in consideration of such circumstances. An object of the invention is to provide a semiconductor device improved in reliability.

Further objects and advantages of the invention will be apparent from the following description of the invention.

### SUMMARY OF THE INVENTION

To achieve the foregoing object, there is provided a semiconductor device configured so that an insulating substrate having a semiconductor element mounted thereon is joined onto a heat radiator.

The semiconductor device includes an insulating substrate; at least one semiconductor element mounted on a first principal surface of the insulating substrate; and a heat radiator joined through a solder member to a second principal surface of the insulating substrate opposite to the first principal surface on which the semiconductor element is mounted, wherein the solder member contains at least tin and antimony; and the antimony content of the solder member is in a range of from 7% by weight to 15% by weight, both inclusively.

According to the configuration, reliability of the semiconductor device can be improved.

### BRIEF DESCRIPTION OF THE DRAWINGS

FIG. 1 is a cross-sectional view showing layers of a semiconductor device according to a first embodiment of the invention.

FIG. 2 is a cross-sectional view showing a sample for evaluating a thermal fatigue lifetime according to the first embodiment.

FIG. 3 is a graph showing crack lengths versus the number of cycles in case where a ceramic substrate according to the first embodiment is made of aluminum oxide.

FIG. 4 is a graph showing crack lengths versus the number of cycles in case where the ceramic substrate according to the first embodiment is made of silicon nitride.

FIG. 5 is a sectional view showing important part of a power semiconductor module according to a second embodiment of the invention.

### DETAILED DESCRIPTION OF PREFERRED EMBODIMENTS

Embodiments of the invention will be described below with reference to the drawings. Incidentally, the technical scope of the invention is not limited to the embodiments. In the drawings, the same or like numerals refer to the same or like parts.

First, a first embodiment of the invention will be described.

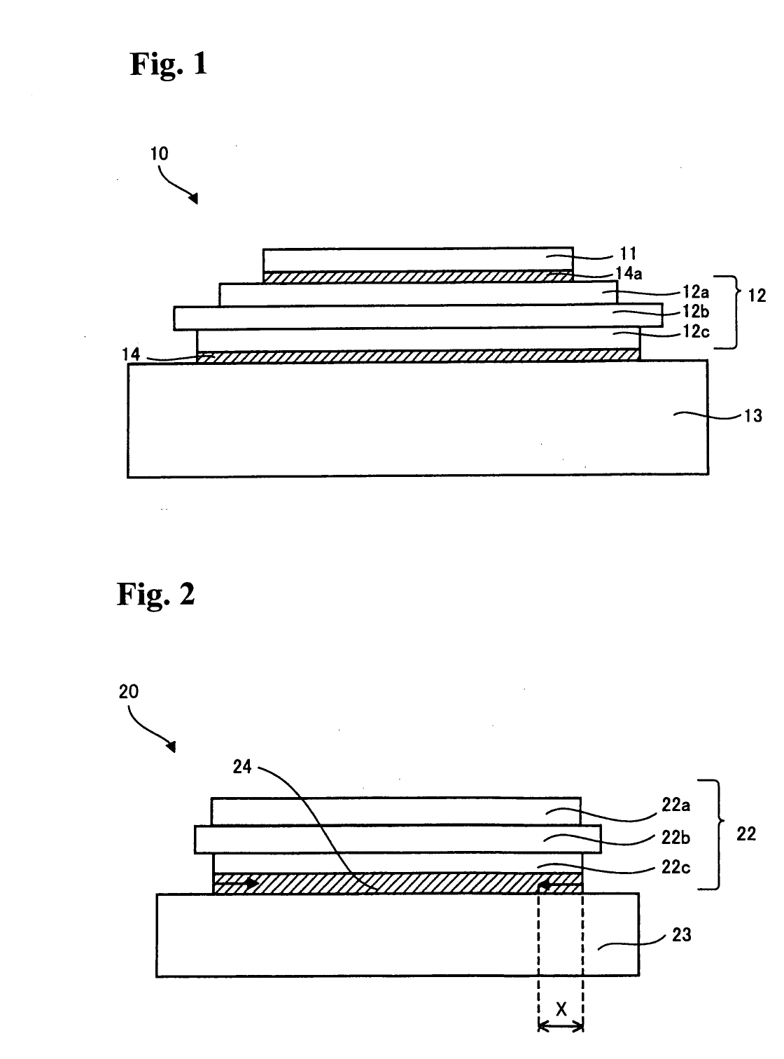

FIG. 1 is a sectional view showing layers of a semiconductor device according to the first embodiment.

As shown in FIG. 1, the semiconductor device 10 includes a semiconductor element 11, an insulating substrate 12 having a principal surface on which the semiconductor element 11 is mounted, and a heat radiator 13 joined to a surface of the insulating substrate 12 opposite to the principal surface.

A front electrode and a rear electrode (both not shown), each being made of a metal film, are provided on opposite surfaces of the semiconductor element 11, respectively. The rear electrode of the semiconductor element 11 is joined to the insulating substrate 12 by a solder member 14a. Any type lead-free (Pb-free) solder alloy such as Sn—Ag alloy, Sn—Cu alloy, Sn—In alloy, Sn—Bi alloy or Sn—Sb alloy (alloy containing Sn as a main component, and one or more elements as additional components selected from Ag, Cu, In, Bi, Sb, etc.) can be used for the solder member 14a. Preferably, the same alloy as used for a solder member 14 which will be described later may be used for the solder member 14a.

For example, the insulating substrate 12 has a ceramic substrate 12b containing any one of Al₂O₃, AlN and Si₃N₄ as a main component. Conducting layers 12a and 12c are joined to opposite surfaces of the ceramic substrate 12b, respectively. The conducting layer 12a is a conducting pattern of metal serving as an electric circuit. The conducting layer 12a is joined through the solder member 14a to the rear electrode of the semiconductor element 11. Similarly, the conducting layer 12c is a conducting pattern of metal serving as an electric circuit. Although the conducting layers 12a and 12c may be made of Al, it is preferable that the conducting layers 12a and 12c are made of Cu which is inexpensive and excellent in heat conduction.

The heat radiator 13 is joined through a solder member 14 to the conducting layer 12c of the insulating substrate 12. For example, the heat radiator 13 serves as a heat conductor for conducting heat to an external cooler of a semiconductor package (not shown). Although the heat radiator 13 may be made of a composite material such as Al—SiC or Cu—Mo, it is preferable that the heat radiator 13 is made of Cu which is inexpensive and excellent in heat conduction.

In the semiconductor device 10 configured as described above, heat distortion caused by the heat expansion coefficient difference between the ceramic substrate 12b and the heat radiator 13 is generated in a junction portion between the conducting layer 12c of the insulating substrate 12 and the heat radiator 13. Because the heat expansion coefficient difference between the ceramic substrate 12b and the heat radiator 13 of Cu is particularly large compared with any other combination, heat distortion generated in the junction portion in this case is relatively remarkable. Although it may be conceived that a material, such as an Al—SiC composite material or a Cu—Mo composite material, having a smaller heat expansion coefficient than that of Cu is used for the heat radiator 13, these composite materials are more expensive than Cu and the heat radiating characteristic of the semiconductor device 10 is lowered because these materials are lower in heat conductivity than Cu.

Therefore, while Cu is used for the conducting layer 12c and the heat radiator 13, an Sn—Sb solder alloy containing Sn as a main component, and 7% by weight to 15% by weight (both inclusively) of Sb, preferably 8% by weight to 10% by weight (both inclusively) of Sb is used as an optimum composition of the solder member 14 used for joining the conducting layer 12c and the heat radiator 13 to each other.

Determination of the optimum composition of the solder member will be described below.

Incidentally, the optimum composition of the solder member is determined in such a manner that the thermal fatigue lifetimes of solder members prepared in advance to have various compositions are evaluated. The compositions of the solder members prepared in advance are Sn—Sb solder alloys containing Sn as a main component and containing 5% by weight of Sb, 6% by weight of Sb, 8% by weight of Sb, 10% by weight of Sb, 13% by weight of Sb and 15% by weight of Sb, respectively.

The evaluation of the thermal fatigue lifetime is performed on samples using these solder members. Incidentally, these solder members are alloys adjusted by dissolving raw materials Sn and Sb in an electric furnace. The purity of each raw material is 99.99% by weight or higher, and each raw material contains impurities inevitably. Accordingly, the respective solder members contain inevitable impurities.

FIG. 2 is a cross-sectional view showing a sample device for evaluating the thermal fatigue lifetime according to the first embodiment.

As shown in FIG. 2, an insulating substrate 22 having a ceramic substrate 22b and conducting layers 22a and 22c of Cu joined to front and rear surfaces of the ceramic substrate 22b is prepared as a substrate for the sample 20. A heat radiator 23 of Cu is joined to the conducting layer 22c of the insulating substrate 22 by a solder member while the composition of the solder member is changed variously. Incidentally, two kinds of ceramics such as Al₂O₃ and Si₃N₄ are used as the ceramic substrate 22b of the insulating substrate 22.

A cooling-and-heating cycle test was applied to each sample 20. In the cooling-and-heating cycle test, a cooling-and-heating cycle for changing the atmospheric temperature of the sample 20 in a range of about −40° C. to about 125° C., both inclusively, was repeated in a range of 2000 cycles to 5000 cycles at intervals of a predetermined time. Each sample 20 was evaluated while the length of a crack X which occurred in a junction portion between the heat radiator 23 and the solder member 24 after such cycles was used as an index. Incidentally, the insulating substrate 22 suffered stress from its outer edge portion toward its central portion. Therefore, in the cooling-and-heating cycle test, the length of a crack X caused in this instance was used as an index of the thermal fatigue lifetime of the sample. The area ratio occupied by the crack may be used in place of the length of the crack as an index of the thermal fatigue lifetime. This is a ratio of the area of the crack produced in the junction portion to the area of contact between the solder member and the conducting layer.

A result of this test will be described below.

First, the case where the ceramic substrate 22b is made of Al₂O₃ will be described.

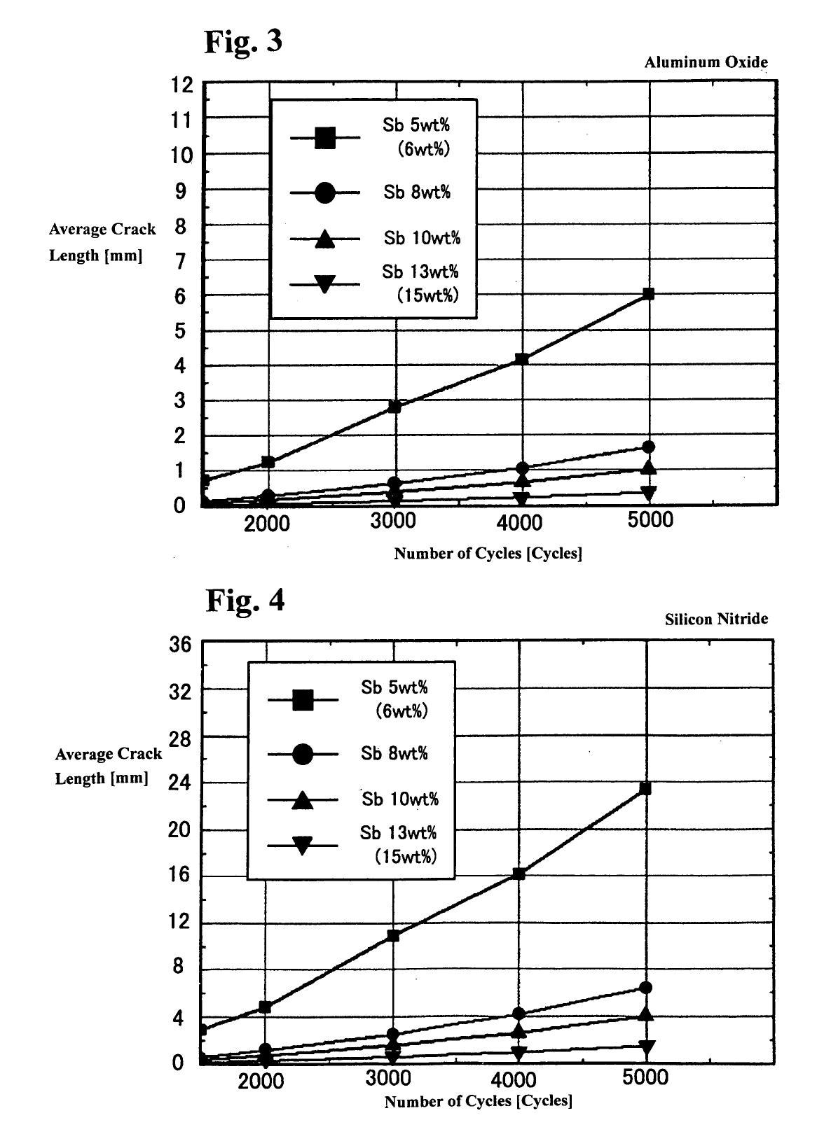

FIG. 3 is a graph showing the length of a crack versus the number of cycles in case where the ceramic substrate according to the first embodiment is made of aluminum oxide. In FIG. 3, the x-axis direction represents the number of cycles in the cooling-and-heating cycle test, and the y-axis direction represents the average crack length [mm] versus the cooling-and-heating cycles. The result obtained when the solder members 24 contained 5% by weight of Sb was almost equal to the result obtained when the solder members 24 contained 6% by weight of Sb. The result obtained when the solder members 24 contained 13% by weight of Sb was almost equal to the result obtained when the solder members 24 contained 15% by weight of Sb. Therefore, FIG. 3 shows data in 5% by weight of Sb and in 13% by weight of Sb, respectively. Although data in 7% by weight of Sb was not shown in FIG. 3, the same effect as in 8% by weight of Sb was observed in 7% by weight of Sb. For example, the thickness of the ceramic substrate 22b made of Al₂O₃ is not smaller than about 0.2 mm but smaller than about 0.4 mm.

As shown in FIG. 3, when the amount of Sb increases to 8% by weight, the average crack length versus the number of cooling-and-heating cycles decreases remarkably. When the amount of Sb further increases, the average crack length decreases. Accordingly, it is found that the thermal fatigue lifetime is improved.

The case where the ceramic substrate 22b is made of Si₃N₄ will be described next.

FIG. 4 is a graph showing the length of a crack versus the number of cycles in case where the ceramic substrate according to the first embodiment is made of silicon nitride. Similarly to FIG. 3, in FIG. 4, the x-axis direction represents the number of cycles in the cooling-and-heating cycle test, and the y-axis direction represents the average crack length [mm] versus the cooling-and-heating cycles. The result obtained when the solder members 24 contained 5% by weight of Sb was almost equal to the result obtained when the solder members 24 contained 6% by weight of Sb. The result obtained when the solder members 24 contained 13% by weight of Sb was almost equal to the result obtained when the solder members 24 contained 15% by weight of Sb. Therefore, FIG. 4 shows data in 5% by weight of Sb and in 13% by weight of Sb, respectively. Although data in 7% by weight of Sb was not shown in FIG. 4, the same effect as in 8% by weight of Sb was observed in 7% by weight of Sb. For example, the thickness of the ceramic substrate 22b made of Si₃N₄ is not smaller than about 0.2 mm but smaller than about 0.7 mm.

Similarly to FIG. 3, as shown in FIG. 4, when the amount of Sb increases to 8% by weight, the average crack length versus the number of cooling-and-heating cycles decreases remarkably. When the amount of Sb further increases, the average crack length decreases. Accordingly, it is found that the thermal fatigue lifetime is improved.

Incidentally, the crack length in the case where Si₃N₄ is used as the insulating substrate is larger than the crack length in the case where Al₂O₃ is used as the insulating substrate even when the two cases are equal in the number of cycles. For example, when the Sb content is 5% by weight and the number of cycles is 3000, the crack length in use of Al₂O₃ is a little smaller than 3 mm but the crack length in use of Si₃N₄ reaches about 11 mm. According to the results shown in FIGS. 3 and 4, it is found that the same lifetime as in use of Al₂O₃ can be kept if the Sb content is not smaller than 8% by weight when the insulating substrate of Si₃N₄ is used.

Although the result obtained in the case where, for example, AlN not thinner than about 0.5 mm but thinner than about 0.8 mm was used as the ceramic substrate 22b is not shown, it was confirmed that the average crack length versus the number of cooling-and-heating cycles decreased remarkably when the Sb content increased to 8% by weight, and then the average crack length decreased as the Sb content further increased, similarly to FIGS. 3 and 4.

The reason why the thermal fatigue lifetime was improved is conceivable as follows. That is, both heat resistance and thermal fatigue strength of the solder member 24 are improved by addition of Sb to Sn. Moreover, the thermal fatigue lifetime is improved because the melting temperature increases to improve heat resistance so that thermal stress prevents Sn crystal particles from coarse-graining. Although the thermal fatigue lifetime is improved as the Sb content increases, there is a possibility that the Sb content higher than 15% by weight may be an obstacle to the assembling process because the liquidus temperature exceeds 300° C.

Accordingly, it is found from the results of the cooling-and-heating cycle test shown in FIGS. 3 and 4 that the solder member 24 containing Sn as a main component and 7% by weight to 15% by weight (both inclusively) of Sb, preferably 8% by weight to 10% by weight (both inclusively) of Sb is suitable for joining the insulating substrate 22 and the heat radiator 23 to each other.

For the aforementioned reason, in the semiconductor device 10 shown in FIG. 1, the solder member 14 containing Sn as a main component and 7% by weight to 15% by weight (both inclusively) of Sb, preferably 8% by weight to 10% by weight (both inclusively) of Sb is used for joining the conducting layer 12c of the insulating substrate 12 and the heat radiator 13 to each other.

In the semiconductor device having the insulating substrate and the heat radiator joined to each other by the solder member made of the aforementioned composition, the thermal fatigue lifetime can be kept long even when a ceramic substrate with a high heat conductivity and a low heat expansion coefficient such as Si₃N₄ or AlN is used in combination with a heat radiating plate of Cu with a low cost and a high heat conductivity. Because it is therefore unnecessary to use an expensive composite material as the heat radiating plate, it is possible to provide a semiconductor device with a high reliability ensured at a low cost.

A second embodiment of the invention will be described below with reference to the drawings.

The second embodiment is an exemplary configuration of a power semiconductor module based on the first embodiment.

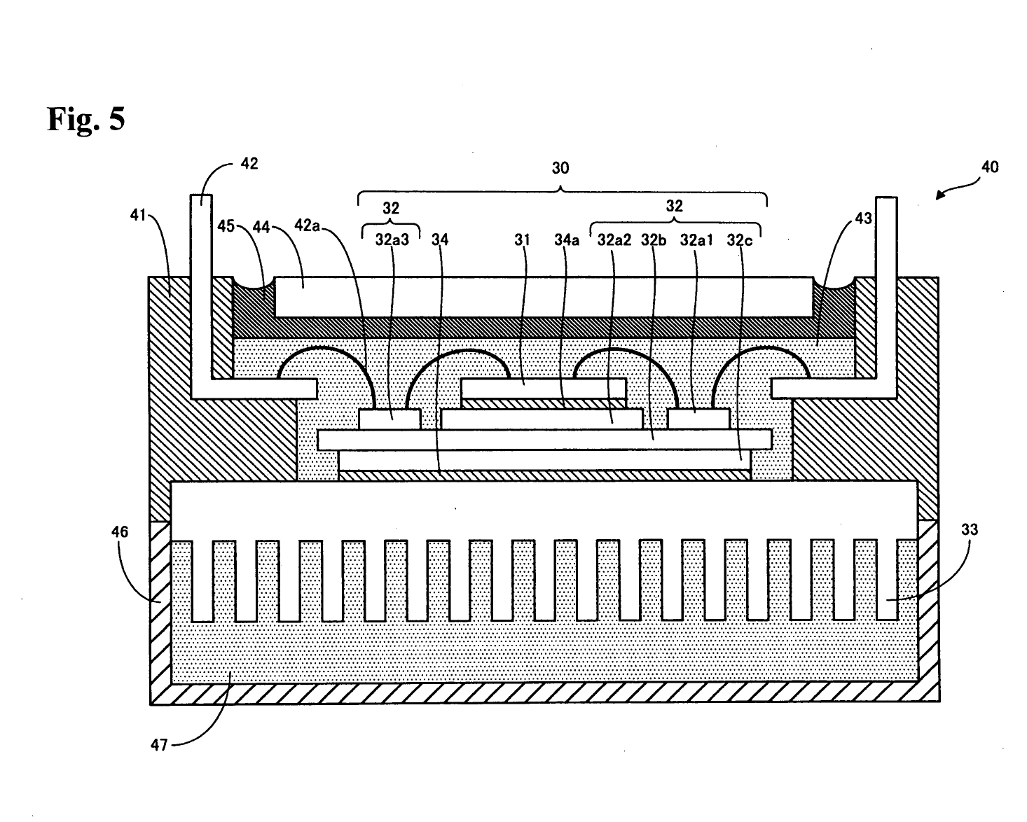

FIG. 5 is a cross-sectional view showing a structure of the power semiconductor module according to the second embodiment.

As shown in FIG. 5, the power semiconductor module 40 includes a semiconductor device 30, lead-out terminals 42, and a heat radiating fin 33. The lead-out terminals 42 are connected through bonding wires 42a to the semiconductor device 30. Incidentally, the heat radiating fin 33 is in contact with a cooler 46 filled with a cooling medium 47. These parts are packed in an enclosure resin casing 41 and an upper portion of the enclosure resin casing 41 is sealed with an upper cover 44 in which a sealing resin agent 45 is embedded.

The semiconductor device 30 has a semiconductor element 31, and an insulating substrate 32. The semiconductor element 31 is mounted on a principal surface of the insulating substrate 32.

A front electrode and a rear electrode (both not shown) made of metal films respectively are provided on opposite surfaces of the semiconductor element 31, respectively. The rear electrode of the semiconductor element 31 is joined to the insulating substrate 32 by a solder member 34a. The same constituent component as a solder member 34 which will be described later is used as the solder member 34a.

For example, similarly to the first embodiment, the insulating substrate 32 has a ceramic substrate 32b containing any one of Al₂O₃, Si₃N₄ and AlN as a main component. Incidentally, when, for example, Al₂O₃ is used, the thickness of the ceramic substrate 32b can be set to be not smaller than about 0.2 mm but smaller than about 0.4 mm. When, for example, Si₃N₄ is used, the thickness of the ceramic substrate 32b can be set to be not smaller than about 0.2 mm but smaller than about 0.7 mm. When, for example, AlN is used, the thickness of the ceramic substrate 32b can be set to be not smaller than about 0.5 mm but smaller than about 0.8 mm.

Conducting layers 32a1, 32a2, 32a3 and 32c are joined to opposite surfaces of the ceramic substrate 32b, respectively. Incidentally, the thickness of each of the conducting layers 32a1, 32a2, 32a3 and 32c can be set to be not smaller than about 0.2 mm but smaller than about 1.0 mm. The conducting layers 32a1, 32a2 and 32a3 are provided as a conductive pattern of a metal which serves as an electric circuit. Particularly, the conducting layer 32a2 is joined to the rear electrode of the semiconductor element 31 through the solder member 34a. Further, the conducting layers 32a1 and 32a3 are connected from the semiconductor element 31 to the lead-out terminals 42 through the bonding wires 42a respectively. The conducting layer 32c is also a conductive pattern of a metal which serves as an electric circuit. Although the conducting layers 32a1, 32a2, 32a3 and 32c may be made of Al, it is preferable that the conducting layers 32a1, 32a2, 32a3 and 32c are made of Cu which is inexpensive and excellent in heat conduction. The conducting layer 32c is joined to the heat radiating fin 33 through the solder member 34.

Each of the solder members 34 and 34a contains Sn as a main component, and 7% by weight to 15% by weight (both inclusively) of Sb, preferably 8% by weight to 10% by weight (both inclusively) of Sb, as described in the first embodiment. Because each of the solder members 34 and 34a does not contain Pb, environmental pollution can be prevented. Incidentally, when the same material as used for the solder member 34 is used for the solder member 34a, reliability on joining the insulating substrate 32 and the semiconductor element 31 is improved more greatly. Moreover, when the same material is used for the solder members 34 and 34a, production can be made easily to reduce the production cost compared with the case where different solder members are used. In addition, it is preferable that germanium (Ge) is added to the solder members 34 and 34a in order to improve joining characteristic between the conducting layer 32c and the heat radiating fin 33 and between the semiconductor element 31 and the conducting layer 32a2.

The lead-out terminals 42 can supply an external voltage to the semiconductor device 30 through the bonding wires 42a.

The enclosure resin casing 41 can contain the semiconductor device 30 in its inside. For example, the enclosure resin casing 41 is made of a PPS (poly phenylene sulfide) resin or a PBT (poly butylene terephthalate) resin. Incidentally, the semiconductor device 30 contained in the inside of the enclosure resin casing 41 is covered and fixed with a gel-state filler 43.

The upper cover 44 serves as a cap for the semiconductor device 30 which is contained in the inside of the enclosure resin casing 41 and fixed with the gel-state filler 43. The upper cover 44 is embedded and fixed by a sealing adhesive agent 45. For example, the upper cover 44 is made of a PPS resin or a PBT resin.

Comb-like grooves are formed in a surface of the heat radiating fin 33 opposite to a surface of contact between the heat radiating fin 33 and the conducting layer 32c of the insulating substrate 32. Although the heat radiating fin 33 may be made of a composite material such as Al—SiC or Cu—Mo, it is preferable that the heat radiating fin 33 is made of Cu which is inexpensive and excellent in heat conduction. The heat radiating fin 33 may be replaced by a heat radiating plate as provided in the first embodiment. In this case, for example, the thickness of the heat radiating plate can be set to be not smaller than about 2 mm but smaller than about 5 mm.

The cooler 46 is attached to the heat radiating fin 33. The inside of the cooler 46 is filled with the cooling medium 47 made of a material such as water or a mixture solution (antifreezing solution) of water and ethylene glycol. The cooling medium is brought into contact with the grooves of the heat radiating fin 33. The combination of the heat radiating fin 33 and the cooler 46 may be replaced by a heat radiating plate which has a flow channel in its inside so that a cooling medium such as water flows in the flow channel and which is brought into contact with the semiconductor device 30.

In the power semiconductor module 40 configured as described above, the thermal fatigue lifetime can be kept long even when a ceramic substrate with high heat conductivity and a low heat expansion coefficient such as Si₃N₄ or AlN is used in combination with a heat radiating plate of Cu with a low cost and a high heat conductivity. Because it is therefore unnecessary to use an expensive composite material as the heat radiating plate, it is possible to provide a semiconductor device with a high reliability ensured at a low cost.

The above description is provided only for explaining principles of the invention. Many changes and modifications can be made by those skilled in the art. The invention is not limited to the exact configuration and applied examples shown and described above. All corresponding modified examples and their equivalences can be regarded as being included in the scope of the invention based on accompanying claims and their equivalences.

The disclosure of Japanese Patent Application No. 2008-135086 filed on May 23, 2008 is incorporated herein by reference in its entirely.

While the invention has been explained with reference to the specific embodiments of the invention, the explanation is illustrative and the invention is limited only by the appended claims.

What is claimed is:

1. A semiconductor device comprising:
an insulating substrate having opposite first and second principal surfaces;
at least one semiconductor element mounted on the first principal surface; and
a heat radiator joined through a solder member to the second principal surface,
wherein the solder member contains at least tin and antimony; and the antimony content of the solder member is in a range from 7% by weight to 15% by weight, both inclusively.

2. The semiconductor device according to claim 1, wherein the at least one semiconductor element is mounted through a lead-free solder alloy on the first principal surface.

3. The semiconductor device according to claim 1, wherein the at least one semiconductor element is mounted through a solder element on the first principal surface, the solder element comprising tin and 7 wt %-15 wt % of antimony.

4. The semiconductor device according to claim 1, wherein the insulating substrate comprises:
a ceramic substrate made of one member selected from the group consisting of aluminum oxide, silicon nitride and aluminum nitride; and
first and second conducting layers made of copper or aluminum and formed on opposite surfaces of the ceramic substrate, the first and second conducting layers respectively forming the first and second principal surfaces of the insulating substrate, and the heat radiator is made of copper or a copper alloy.

5. The semiconductor device according to claim 1, wherein the solder member further contains germanium.

6. The semiconductor device according to claim 1, wherein the heat radiator is a heat radiating plate.

7. The semiconductor device according to claim 6, wherein the heat radiating plate includes a flow path in which a cooling medium for cooling the heat radiating plate flows.

8. The semiconductor device according to claim 1, wherein the heat radiator is a heat radiating fin.

9. The semiconductor device according to claim 8, wherein the heat radiating fin is in contact with the cooling medium for cooling the heat radiating fin.

10. The semiconductor device according to claim 1, wherein the antimony content of the solder member is in a range of from 8% by weight to 10% by weight, both inclusively.
